(19) United States
(12) Patent Application Publication
(10) Pub. No.: US 2002/0132497 A1
(43) Pub. Date: Sep. 19, 2002

(54) Substrate processing apparatus and method for manufacturing semiconductor device

(75) Inventor: Kouji Tometsuka, Nakano-ku (JP)

Correspondence Address: OLIFF & BERRIDGE, PLC, P.O. BOX 19928, ALEXANDRIA, VA, 22320, US

(73) Assignee: Hitachi Kokusai Electric Inc., Tokyo (JP)

(21) Appl. No.: 10/097,624

(22) Filed: Mar. 15, 2002

(30) Foreign Application Priority Data
Mar. 19, 2001 (JP) 2001-079056

(51) Int. Cl. H01L 21/31; H01L 21/469

(52) U.S. Cl. 438/782; 438/778

(57) ABSTRACT

An substrate processing apparatus and a method for manufacturing a semiconductor device can effectively prevent a reaction gas from flowing into a rotation mechanism form a reaction chamber. A vertical CVD apparatus is for processing wafers while rotating the wafers by a rotation shaft 41 of a rotation mechanism 40 during introducing a reaction gas into a reaction chamber 25 as well as exhausting the reaction gas. Between the rotation shaft 41 of this apparatus and a furnace opening cover 32 being a non-rotational portion of the reaction chamber 25 into which the shaft 41 is inserted, there is provided a sealing portion 50 with a labyrinth structure comprising a rotor 51 and a stator 52 so as to prevent a reaction gas from flowing into the mechanism 40 from the reaction chamber 25 via a clearance 54. An upper opening 53 of the clearance 54 communicating with a side of the reaction chamber 25 is arranged at a side of the rotation shaft 41 rather than an opposite side of the shaft 41 remote from the shaft 41 and an upper opening diameter R of the clearance 54 with the shaft 41 as center is designed to be small.

### BACKGROUND OF THE INVENTION

1. Field of the Invention

This invention relates to a substrate processing apparatus for processing a substrate to be processed while rotating the substrate and a method for manufacturing a semiconductor device using this substrate processing apparatus, and particularly to a substrate processing apparatus wherein a sealing portion of a rotation shaft for rotating a substrate to be processed is improved.

2. Description of the Related Art

As a sealing portion structure of a rotation shaft in a substrate processing apparatus, a sealing portion structure, for example, described in Japanese Patent Applications Laid-Open No. 2000-286204 (hereafter referred to as the known example 1) and Japanese Patent Applications Laid-Open No. 6-302533 (hereafter referred to as the known example 2), is conventionally known.

A sealing portion structure described in the known example 1 is a sealing portion structure in a vertical type diffusion apparatus which allows a reaction gas to be introduced from an upper portion of a reaction chamber and to be exhausted through a lower portion the reaction chamber in a normal pressure process such as oxidation and the like wherein, in order to prevent corrosion by the reaction gas of a metal parts such as a boat rotation shaft and the like, a clearance with concavities and convexities in shape is formed by a lower boat surface and an upper furnace opening cover surface, and N₂ gas is further injected into the above-mentioned clearance with concavities and convexities in shape from a side of a rotation center. A sealing portion structure described in the known example 2 is another sealing portion structure wherein, in order to prevent a reaction gas from approaching a boat rotation portion, a clearance with concavities and convexities in shape similar to that of the known example 1 is also formed between a lower boat surface and an upper furnace opening cover surface.

In the above-mentioned known examples 1 and 2, there are problems as follows.

(1) The sealing portions as described in the known examples 1 and 2 form a clearance with concavities and convexities in shape on opposite surfaces throughout the lower boat surface and the upper furnace opening cover surface. An opening of the clearance communicating with a side of the reaction chamber is opened at a position most distant from the rotation shaft. An opening diameter of the clearance with the rotation shaft as center is large and an opening area is also large. Even if an inert gas such as N₂ and the like is allowed to flow from this opening having a large area, it is difficult to allow the gas to flow out from the opening uniformly and a reaction gas enters from the place where the inert gas flows out weakly. In order to prevent this, however, if a large amount of N₂ gas is allowed to flow, the reaction gas is diluted so as to cause a malfunction in substrate processing.

(2) Although the sealing portions described in the known examples 1 and 2 are effective in a diffusion apparatus, they are not effective in a CVD apparatus. That is, in the diffusion apparatus as in the known example 1. a reaction gas is supplied from the upper portion of the reaction chamber which is distant from the sealing portion and the reaction gas is exhausted from the lower portion close to the sealing portion. Therefore, regardless of whether the inert gas flows strongly or weakly, the proportion of the reaction gas which is drawn from an exhaust opening close to the sealing portion is larger than the proportion of the reaction gas which flows into the sealing portion. In addition, so is the case when a large amount of N₂ gas is introduced from the sealing portion. Accordingly, the flowing of the reaction gas into the clearance as mentioned in the above-noted (1) presents only a little problem, if any. However, in an apparatus wherein a reaction gas is supplied from a lower portion of a reaction chamber which is close to a sealing portion and the reaction gas is exhausted from an upper portion distant from the sealing portion, such as a CVD apparatus rather than a diffusion apparatus, if N₂ gas is injected from the sealing portion, the reaction gas is diluted so as to provide an effect on film formation, because the reaction gas is supplied from the lower portion of the reaction chamber in such an apparatus. Therefore, the problem of the above-noted (1) may be shown in close-up or may loom large. In addition, although the known example 2 does not clearly describe location of the gas supply and exhaust openings of the reaction gas with regard to the reaction chamber as in the known example 1, the known example 2 is as in the case of the known example 1 because the known example 2 exemplifies a diffusion process.

### SUMMARY OF THE INVENTION

An object of the present invention is to provide a substrate processing apparatus wherewith, by resolving the problems with the prior art noted in the foregoing, a reaction gas is effectively prevented from flowing into a rotation mechanism from a reaction chamber without injecting a gas and to provide a method for manufacturing a semiconductor device using this substrate processing apparatus. Moreover, an object of the present invention is to provide a substrate processing apparatus and a method for manufacturing a semiconductor device wherewith prevention of a reaction gas flowing into a rotation mechanism is also effective in a CVD apparatus.

A substrate processing apparatus of a first invention is characterized by a substrate processing apparatus for processing a substrate to be processed while rotating the substrate by a rotation shaft of a rotation mechanism during introducing a reaction gas into a reaction chamber as well as exhausting the reaction gas, the apparatus comprising: a sealing portion for preventing a reaction gas from flowing into the rotation mechanism from the reaction chamber via a clearance which is formed, with the rotation shaft as center, between the rotation shaft and a non-rotational portion, which the rotation shaft penetrates, of the reaction chamber, wherein an opening of the clearance communicating with a side of the reaction chamber is arranged at a side of the rotation shaft rather than an opposite side of the rotation shaft remote from the rotation shaft. According to the present invention, since an opening location of the clearance communicating with a side of the reaction chamber is provided at a side of the rotation shaft, an opening diameter of the clearance with the rotation shaft as center can be designed to be small. Therefore, the opening area is smaller compared to the case where an opening location of the clearance is provided at the opposite side of the rotation shaft, thereby being able to effectively prevent a reaction gas inside of the reaction chamber from flowing into a rotation mechanism without injecting a gas from the clearance of the sealing portion.

In the first invention, it is preferable that the reaction chamber be provided with a gas supply opening at one side of the reaction chamber and with a gas exhaust opening at the other side of the reaction chamber, and the sealing portion be arranged at a location of a side of the gas supply opening rather than the gas exhaust opening. In the case that the sealing portion is arranged at a location of a side of the gas supply opening rather than the gas exhaust opening, the probability becomes high that the reaction gas inside of the reaction chamber flows into the close clearance opening rather than the distant gas exhaust opening. However, if an opening diameter of the clearance is designed to be small so as to make the reaction gas difficult to flow into the close clearance opening, it is possible to more effectively prevent the reaction gas inside of the reaction chamber from flowing into a rotation mechanism.

In addition, in the first invention, it is preferable that the sealing portion be arranged at an upstream side of the reaction gas rather than the substrate to be processed. In the case that the sealing portion is arranged at an upstream side of the reaction gas rather than the substrate to be processed, the probability becomes high that the reaction gas inside of the reaction chamber flows into the clearance opening. However, if an opening diameter of the clearance is designed to be small so as to make the reaction gas difficult to flow into the clearance opening, it is possible to more effectively prevent the reaction gas inside of the reaction chamber from flowing into a rotation mechanism.

Moreover,in the first invention, it is preferable that the sealing portion be kept at a temperature of 150° C. or more. If the sealing portion is kept at a temperature of 150° C. or more, reaction products generated when processing the substrate to be processed which might have adhered to the sealing portion is easily released from the sealing portion, thereby being able to inhibit increased adherence of the reaction products.

Furthermore, in the first invention, it is preferable that the sealing portion be formed in such a way that a first convex portion extending from the rotation shaft and a second convex portion extending from the non-rotational portion are engaged with each other via a clearance. This construction can enhance the sealing capability, thereby being able to more effectively prevent the reaction gas inside of the reaction chamber from flowing into a rotation mechanism.

Additionally, a substrate processing apparatus of a second invention is characterized by a substrate processing apparatus for processing a substrate to be processed while rotating the substrate by a rotation shaft of a rotation mechanism during introducing a reaction gas into a reaction chamber as well as exhausting the reaction gas, the apparatus comprising: a rotation shaft and a non-rotational portion, which the rotation shaft penetrates, of the reaction chamber; and a sealing portion having a first convex portion extending from the rotation shaft and a second convex portion extending from the non-rotational portion, that is formed in such a way that the first and second convex portions are engaged with each other via a clearance, wherein the second convex portion is located at a side of a substrate rather than the first convex portion. According to this invention, if the second convex portion is located at a side of a substrate rather than the first convex portion, it is possible to allow an opening portion of the clearance communicating with the reaction chamber to be small, compared to the case where the first convex portion is located at a side of a substrate rather than the second convex portion, thereby being able to effectively prevent a reaction gas inside of the reaction chamber from flowing into a rotation mechanism without injecting a gas from the clearance of the sealing portion.

Moreover, a method for manufacturing a semiconductor device of a third invention is characterized by a method for manufacturing a semiconductor device that processes a substrate to be processed while rotating the substrate by a rotation shaft of a rotation mechanism during introducing a reaction gas into a reaction chamber as well as exhausting the reaction gas, the method comprising: forming a thin film on the substrate to be processed, by using a substrate processing apparatus which comprising: a sealing portion for preventing a reaction gas from flowing into the rotation mechanism from the reaction chamber via a clearance which is formed, with the rotation shaft as center, between the rotation shaft and a non-rotational portion, which the rotation shaft penetrates, of the reaction chamber, wherein an opening of the clearance communicating with a side of the reaction chamber is arranged at a side of the rotation shaft rather than an opposite side of the rotation shaft remote from the rotation shaft. According to the method of the present invention, since an opening location of the clearance communicating with a side of the reaction chamber is provided at a side of the rotation shaft, an opening diameter of the clearance with the rotation shaft as center can be designed to be small. Therefore, the opening area is smaller compared to a sealing portion having a larger opening diameter, thereby being able to effectively prevent a reaction gas from flowing into a rotation mechanism from the reaction chamber.

In the third invention, it is preferable that the sealing portion be arranged at an upstream side of the reaction gas rather than the substrate to be processed. In the case that the sealing portion is arranged at an upstream side of the reaction gas rather than the substrate to be processed, the probability becomes high that the reaction gas inside of the reaction chamber flows into the clearance opening. However, if an opening diameter of the clearance is designed to be small so as to make the reaction gas difficult to flow into the clearance opening, it is possible to more effectively prevent the reaction gas inside of the reaction chamber from flowing into a rotation mechanism.

Furthermore, in the third invention, it is preferable that the sealing portion be formed in such a way that a first convex portion extending from the rotation shaft and a second convex portion extending from the non-rotational portion are engaged with each other via a clearance. This construction can enhance the sealing capability, thereby being able to more effectively prevent the reaction gas inside of the reaction chamber from flowing into a rotation mechanism.

### BRIEF DESCRIPTION OF THE DRAWINGS

FIG. 1 is a view for illustrating a detailed lower structure of a vertical CVD apparatus according to a first embodiment adapted to be a substrate processing apparatus of the present invention;

FIG. 2 is an explanatory view for illustrating principal portions of a lower structure of a vertical CVD apparatus according to a second embodiment;

FIG. 3 is a view for illustrating principal portions of a lower structure of a vertical CVD apparatus according to a third embodiment; and

FIG. 4 is a view for illustrating a general vertical CVD apparatus which is common to the embodiments adapted to be a substrate processing apparatus of the present invention.

### DESCRIPTION OF THE PREFERRED EMBODIMENTS

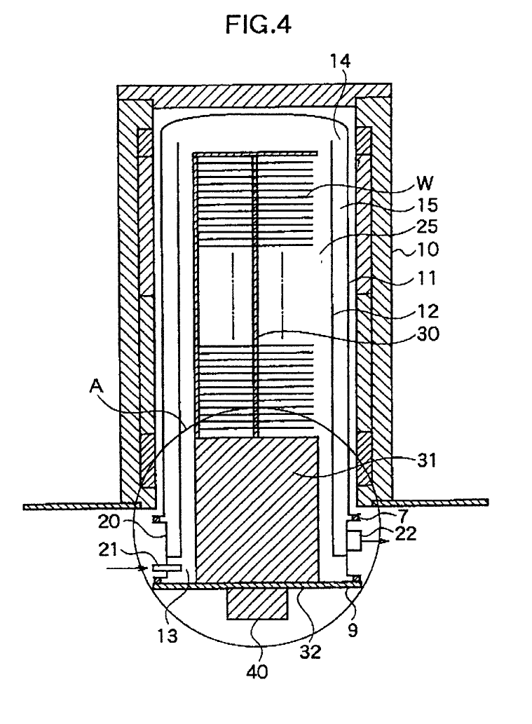

Embodiments of the present invention will be described below. FIG. 4 shows a schematic view of a construction of an embodiment of a vertical CVD apparatus adapted to be a substrate processing apparatus for performing a method for manufacturing a semiconductor device of the present invention.

Inside of a cylindrical heater 10 which is closed at its upper portion, there is provided an outer reaction tube 11, and within the outer reaction tube 11, there is concentrically provided an inner reaction tube 12 which constructs a reaction chamber 25 with an upper end being opened. The outer reaction tube 11 and the inner reaction tube 12 are vertically disposed on a furnace opening flange 20, and the outer reaction tube 11 and the furnace opening flange 20 are sealed therebetween by an O-ring 7. A lower end of the furnace opening flange 20 is airtightly covered with a furnace opening cover 32 via an O-ring 9, and a boat 30 which is vertically disposed on the furnace opening cover 32 via a cap 31 is inserted into the reaction chamber 25 within the inner reaction tube 12. In the boat 30, wafers W as a substrate to be processed are loaded being horizontally oriented in a multi-storied fashion. The boat 30 is designed to rotate while the furnace opening cover 32 is a non-rotational portion. Rotation of the boat 30 is performed by a rotation mechanism 40 which is attached to the furnace opening cover 32.

A gas introducing port 21 is in communication with the furnace opening flange 20 at a location under the inner reaction tube 12, and a gas exhaust port 22 is connected to an upper portion of the furnace flange 20 to communicate with a lower end of a cylindrical space 15 which is formed between the outer reaction tube 11 and the inner reaction tube 12, Thus, in this vertical CVD apparatus, since a gas supply opening 13 of the reaction chamber 25 is formed at an outlet of the gas introducing port 21, the gas supply opening 13 is located at a lower portion of the reaction chamber 25. In addition, since a gas exhaust opening 14 of the reaction chamber 25 is formed at an upper end of the cylindrical space 15, the gas exhaust opening 14 is located at an upper portion of the reaction chamber 25. Moreover, a sealing portion is located not at a downstream side of the wafers W with respect to the gas flow introduced from the gas supply opening but at an upstream side of the wafers W.

The boat 30 is moved down by a boat elevator which is not shown in the drawing, and wafers W are loaded onto the boat 30, and then, the boat 30 is inserted into the reaction chamber 25 within the inner reaction tube 12 by the boat elevator. After the furnace opening cover 32 completely covers a lower end of the furnace opening flange 20, the reaction chamber 25 within the inner reaction tube 12 and the outer reaction tube 11 is exhausted.

While being supplied into the reaction chamber 25 from the gas introducing port 21, a reaction gas is exhausted from the gas exhaust port 22. The reaction space 25 is heated by a heater 10 to a wafer processing temperature, and then, film formation is performed on a surface of the wafers W. After completing the film formation, an inert gas is introduced from the gas introducing nozzle 21 so that the atmosphere inside of the reaction tubes 11 and 12 is substituted for the inert gas, and then, the interiors of the outer and inner tubes 11 and 12 are returned to a normal pressure. Next, the boat 30 is moved down to draw out the wafers W on which the film formation has been completed.

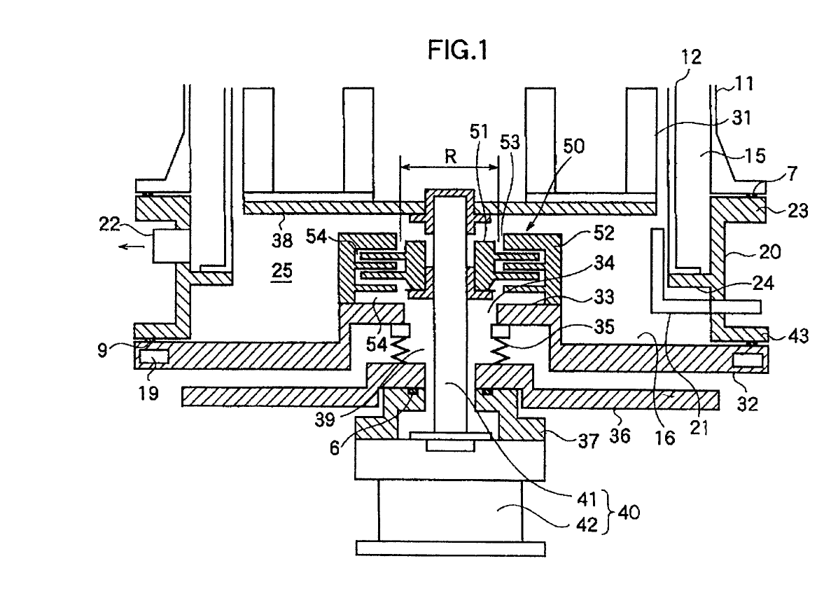

FIG. 1 shows a view for illustrating a detailed lower structure of a vertical CVD apparatus according to a first embodiment, as surrounded by a circle A in FIG. 4. This view is a side sectional view illustrating a state in which a furnace opening 16 of the furnace flange 20 is covered with the furnace opening cover 32.

The furnace opening flange 20 which forms the furnace opening 16 directed downwardly is provided at a lower end of the outer reaction tube 11. At an upper end of the furnace opening flange 20, there is provided a relatively large horizontal flange 23 on which the outer reaction tube 11 is vertically disposed via the O-ring 7. On an inner wall of the furnace opening flange 20, there is provided a convex portion 24 which extends radially inwardly from the inner wall, and the inner reaction tube 12 is vertically disposed on the convex portion 24. At a lower end of the furnace opening flange 20, there is provided a relatively large horizontal flange 43, and at the same time, the outer diameter of the furnace opening cover 32 is enlarged in accordance with the flange 43.

The gas introducing port 21 and the exhaust port 22 are provided at a circumferential wall portion of the furnace opening flange 20. When a reaction gas introduced from the gas introducing port 21, the reaction gas flows through inside of the inner reaction tube 12 upwardly, and then, flows through the space 15 between the outer reaction tube 11 and the inner reaction tube 12 downwardly, to be exhausted from the gas exhaust port 22 to outside.

The boat (not shown in the drawing) in which the wafers W are loaded being horizontally oriented in a multi-storied fashion is designed to be freely inserted into and drawn out from the reaction chamber 25 within the inner reaction tube 12, and is mounted on the cap 31 provided on a cap rest 38. The furnace opening cover 32 is located at a lower side of the cap rest 38. The furnace opening cover 32 is in intimate contact with a lower surface of an enlarged outer diameter of the furnace opening flange 20, and air-tightly seals the furnace opening 16 via an O-ring 9 fitted in an annular groove. At a lower side of this furnace opening cover 32 (outside of the reaction chamber 25), there is provided a boat elevator board 36 via a bellows 35. A driving portion 42 of the rotation mechanism 40 is connected to a lower side of the boat elevator board 36 via a connecting pipe 37. The rotation mechanism 40 mainly comprises a rotation shaft 41 and a rotation portion 42. The boat elevator board 36 which allows the boat and the rotation mechanism 40 along with the furnace opening cover 32 to move up and down, is supported by an elevator slide (not shown in the drawing) of the boat elevator. The boat is inserted into or drawn out from the reaction chamber 25 by allowing this boat elevator board 36 to move up or down.

The rotation shaft 41 of the rotation mechanism 40 which is extended upwardly from the driving portion 42 through the connecting pipe 37, a central aperture of the boat elevator board 36, the bellows 35 and a central aperture 34 of the furnace opening cover 32, is secured to the cap rest 38. Accordingly, it is possible to rotate the boat (not shown in the drawing) in a horizontal surface via the cap rest 38 by rotationally driving the rotation shaft 41 with the driving portion 42.

At an area of the rotation shaft 41 between the cap rest 38 and the furnace opening cover 32, there is provided a magnetic bearing sealing portion 50 which rotationally supports the rotation shaft 41 as well as seals the reaction chamber 25 between an interior and an exterior at a location where the rotation shaft 41 is inserted into the reaction chamber 25. The sealing portion 50 comprises a stator 52 and a rotor 51 with a labyrinth structure. The stator 52 is vertically disposed on a central convex portion 33 of the furnace opening cover 32, and many concavities and convexities which are radially recessed as well as extend are axially formed on an inner circumferential surface of the stator 52. The central convex portion 33 may be provided integrally with the stator 52. This stator 52 constructs a second convex portion.

The rotor 51 is provided on an outer circumferential surface of a corresponding area of the rotation shaft 41 which penetrates through the central aperture 34 of the central convex portion 33. On an outer circumferential surface of the rotor 51, there are formed many concavities and convexities which are engaged with the convexities and concavities of the inner circumferential surface of the stator 52 via a clearance 54. A labyrinth seal is formed between the furnace opening cover 32 and the rotation shaft 41 with the concavities and convexities and the convexities and concavities. This rotor 51 constructs a first convex portion. The clearance 54 of the sealing portion 50 is formed with the rotation shaft as center, radially or axially, and a reaction gas within the reaction chamber 25 is prevented from flowing into a rotation shaft chamber 39 via this clearance 54. Here, the rotation shaft chamber 39 which is formed around an outer circumference of the rotation shaft 41 between the sealing portion 50 and the driving portion 42 is a chamber surrounded by the sealing portion 50, the furnace opening cover 32, the bellows 35, the boat elevator board 36, the connecting pipe 37, the driving portion 42 and the rotation shaft 41.

Operation or working of the construction as mentioned above will be explained below.

In this construction, when the boat is moved up by driving the boat elevator, the furnace opening cover 32 is in intimate contact with the lower surface of the flange 43 at the lower end of the furnace opening flange 20 when the elevation action ends so that the furnace opening cover 32 covers the furnace opening 16. After covering the furnace opening 16, the interior of the reaction chamber 25 is set under a reduced pressure, and the boat is rotated by the rotation mechanism 40. While being supplied into the reaction chamber 25 from the gas introducing port 21, a reaction gas is exhausted from the gas exhaust port 22. In this case, since the rotation shaft sealing portion 50 is sealed by the labyrinth mechanism, leakage of the reaction gas from the side of the reaction chamber 25 to the rotation mechanism 40 is inhibited.

Here, since the sealing portion 50 comprises the stator 52 and the rotor 51 provided around the outer circumference of the rotation shaft 41, and since the concavity convexity repeating engagement of the sealing portion 50 is formed in a direction of the rotation shaft 41, a location of an upper opening 53 of the clearance 54 communicating with the reaction chamber 25 is at a side of the rotation shaft 41 so that an upper opening diameter R with the rotation shaft 41 as center is smaller, compared to a seal portion which is formed by a lower boat surface and an upper furnace opening cover surface has repeating concavities and convexities formed in a radial direction of the rotation shaft 41. Particularly in the illustrated embodiment, with respect to an innermost side engagement end of the concavity convexity engagement of the sealing portion 50 which is at a side of the reaction chamber 25, the engagement at a side of the stator 52 is formed by the convex portion which is directed radially inwardly and the engagement at a side of the rotor 51 is formed by the concave portion which is directed radially inwardly. As a result, a location of the upper opening 53 of the clearance 54 communicating with the side of the reaction chamber 25 is provided still at the side of or still closer to the side of the rotation shaft 41 so that the upper opening diameter R with the rotation shaft 41 as center is still smaller compared to the case where the location of the upper opening 53 of the clearance 54 is provided at a location in the direction remote from the rotation shaft 41 when the concavity convexity relation of the innermost side engagement end is set in the opposite relation.

Thus, since the opening area of the clearance 54 of the labyrinth seal by the sealing portion 50 is designed to be small, it is possible to substantially inhibit reaction gas leakage from the side of the reaction chamber 25 to the rotation mechanism 40 without injecting a gas from the clearance 54. Accordingly, in film formation while rotating a boat, it is possible to effectively avoid a failure of the rotation mechanism 40 caused by adherence of reaction products to the rotation mechanism 40, mixing of reaction products, corrosion of the rotation mechanism 40, and the like. As a result, the apparatus can operate with long-term stability.

It is preferable that the above-mentioned sealing portion 50 be kept at a temperature of 150° C. or more. This is because, if the sealing portion is kept at a temperature of 150° C. or more, reaction products generated when processing the wafers W which might have adhered to the sealing portion 50 is easily released from the sealing portion 50, thereby being able to inhibit increased adherence of the reaction products. Heating and keeping the sealing portion 50 at a temperature of 150° C. can be achieved by utilizing heat radiation from the inner reaction tube 12. The furnace opening cover 32 and the like which are lower portions below the sealing portion 50 (at the opposite side to the reaction chamber) are kept at a lower temperature of 150° C. or less. For example, in order to keep the furnace opening cover 32 at a temperature of 150° C. or less, the enlarged outer diameter portion of the furnace opening cover 32 may be designed to be a jacket structure provided with a flow passage 19 so as to perform forced fluid cooling in the vicinity of the O-ring 9. Alternatively, since the lower portions below the sealing portion 50 are in contact with outside air, the portions may be kept at the lower temperature by natural cooling by themselves.

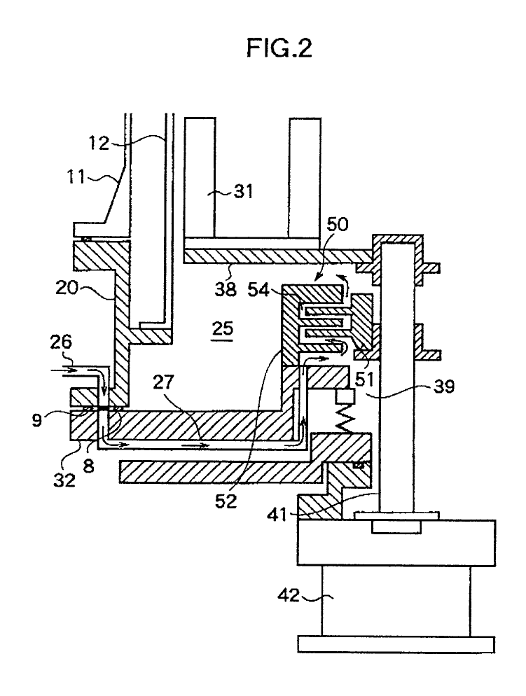

The above-mentioned first embodiment has been explained in the case where the clearance opening area of the sealing portion 50 with a labyrinth structure is designed to be small so that the rotation shaft 41 is sealed. In order to further ensure the sealing, a gas may be injected from the clearance of the labyrinth seal without dilution of a reaction gas. FIG. 2 is a view for illustrating principal portions of a lower structure of a vertical CVD apparatus which shows such a second embodiment. Here, a reaction species gas of the reaction gas which comprises the reaction species gas and a reaction medium gas, is introduced into the reaction chamber 25 from the gas introducing port which is not shown in the drawing, and the remaining reaction medium gas of the reaction gas is allowed to flow from the clearance of the above-mentioned labyrinth seal.

In FIG. 2, the same reference numerals designate the same elements as described in FIG. 1 and descriptions for such elements will be omitted. An auxiliary gas introducing pipe 27 which introduces a gas into the rotation shaft chamber 39 through the central convex portion 33 is connected to the central convex portion 33 of the furnace opening cover 32. The gas introduced from the auxiliary gas introducing pipe 27 is the remaining reaction medium gas of the reaction gas which comprises the reaction species gas and the reaction medium gas. The auxiliary gas introducing pipe 27 is extended along a back surface of the furnace opening cover 32 at an opposite side to the reaction chamber 25 to the vicinity of the outer circumferential portion and is joined to the furnace opening cover 32 from the lower side. A base end opening of the auxiliary gas introducing pipe 27 is, then, formed on an upper surface (mating surface) of the furnace opening cover 32. The mating surface of the furnace opening cover 32 is provided with inner and outer double O-rings 8 and 9 which are fitted in annular grooves. The above-mentioned base end opening is located between the inner O-ring 8 and the outer O-ring 9 which maintain air-tight sealing between the furnace opening cover 32 and the furnace opening flange 20.

In addition, an auxiliary gas supply pipe 26 is connected to an upper side of the flange 43 with an enlarged outer diameter which is located at the lower end of the furnace opening flange 20. An extreme end opening of the auxiliary gas supply pipe 26 is provided on a lower surface (mating surface) of the above-mentioned flange 43. This extreme end opening is brought into air-tight communication with the base end opening of the auxiliary gas introducing pipe 27 by allowing the upper surface of the furnace flange cover 32 to be in intimate contact with the lower surface of the flange 43 at the side of the furnace opening flange 20.

The furnace opening 16 is, then, covered with the furnace opening cover 32, and at the same time, the auxiliary gas supply pipe 26 and the auxiliary gas introducing pipe 27 are in connected state so as to construct an introducing path for the reaction medium gas in the form of penetration into the furnace opening cover 32, thereby being able to introduce the reaction medium gas via the path into the rotation shaft chamber 39 from the central convex portion 33 of the furnace opening cover which faces the lower opening 54 of the sealing portion 50 of the rotation shaft 41. The double O-rings 8 and 9 are located on the circumferential portion mating surfaces (intimate contact surfaces of the furnace opening cover 32 and the flange 43) so as to surround the communicating portion of the auxiliary gas introducing pipe 27 and the auxiliary gas supply pipe 26, thereby attaining highly air-tightly sealed connection.

In the structure of FIG. 2, when the boat is moved up by driving the boat elevator, the furnace opening cover 32 is in intimate contact with the lower surface of the flange 43 at the lower end of the furnace opening flange 20 when the elevation action ends so that the furnace opening cover 32 covers the furnace opening 16. After covering the furnace opening 16, the interior of the reaction chamber 25 is set under a reduced pressure, and the boat is rotated by the rotation mechanism 40. On the one hand, while being supplied into the reaction chamber 25 from the gas introducing port 21, the reaction species gas is exhausted from the gas exhaust port 22. On the other hand, as indicated by arrows in FIG. 2, the remaining reaction medium gas of the reaction gas is supplied into the rotation shaft chamber 39 from the interconnected auxiliary gas supply pipe 26 and auxiliary gas introducing pipe 27, and then, is introduced into the reaction chamber 25 via the clearance 54 of the sealing portion 50. In this case, since the rotation shaft sealing portion 50 is provided with the labyrinth mechanism as well as the reaction medium gas is injected from the auxiliary gas introducing pipe 27 via the clearance 54 of the rotation shaft sealing portion 50, leakage of the reaction species gas from the side of the reaction chamber 25 to the rotation mechanism 40 is inhibited. Accordingly, in film formation while rotating a boat, it is possible to effectively avoid a failure of the rotation mechanism 40 caused by adherence of reaction products to the rotation mechanism 40, mixing of reaction products, corrosion of the rotation mechanism 40, and the like. As a result, the apparatus can operate with long-term stability.

Moreover, the gas which is introduced from the auxiliary gas introducing pipe 27 via the sealing portion 50 is not a inert gas for purging but the reaction medium gas of the reaction gas which is originally introduced into the reaction chamber 25, thereby being able to prevent a gas mixing ratio of the reaction gas introduced into the reaction chamber 25 from varying compared to the apparatus which introduces the inert gas for purging. As a result, a high quality semiconductor film can be manufactured with long-term stability.

It is preferable that the reaction medium gas be an inert gas in a reaction gas. For example, in the case that a film type formed on wafers is Si₃N₄, beginning with dichlorosilane SiH₂Cl₂, SiH₄, SiCl₄, and SiHCl₃ (reaction species), and NH₃ ammonia (reaction medium) are used as the reaction gas. In this case, it is preferable that NH₃ ammonia gas (reaction medium) be allowed to flow as the reaction medium gas.

Furthermore, since in the present embodiment the opening diameter R of the sealing portion clearance 54 is set to be small, it is possible to allow a gas to flow out from this opening uniformly even in the case of a small amount of the gas. Therefore, since the influence of the gas on film formation is small, in place of the reaction medium gas, an inert gas such as N₂ gas and the like which is irrelevant to the reaction gas may be allowed to flow.

In the mean time, the first and second embodiments explained by using FIG. 1 and FIG. 2, have been explained in the case where the repeating concavities and convexities of the sealing portion are formed in the direction of the rotation shaft in order to allow the opening diameter of the clearance to be small. However, if a rotor is located below, a stator located above to cover the rotor such that the rotor and the stator are engaged with each other between the opposite surfaces, it is possible to form repeating concavities and convexities radially while maintaining a small opening diameter of a clearance.

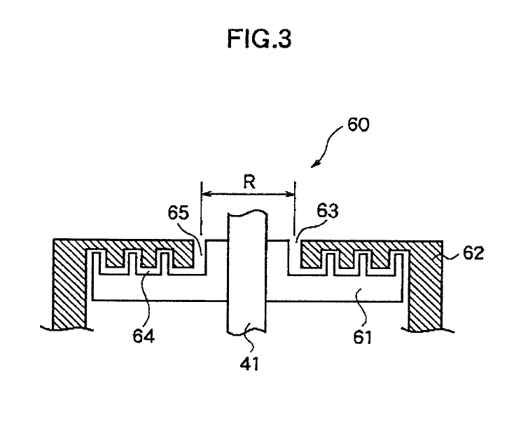

FIG. 3 is a view for illustrating principal portions of a lower structure of a vertical CVD apparatus which shows a third embodiment having such a sealing portion 60. On an upper portion inner circumferential surface at an opposite side of the reaction chamber 25 of a cylindrical stator 62 which is vertically disposed on the central convex portion of the furnace opening cover 32, there are radially formed many concavities and convexities which are axially recessed as well as extend. The rotation shaft 41 which penetrates through a central aperture 65 of the stator 62 is provided with a disk-shaped rotor 61, and on a surface at a side of the reaction chamber of a corresponding area of the rotor 61, there are formed many convexities and concavities which are in engagement with the concavities and convexities on the inner circumferential surface of the stator 62 via a clearance 64. A labyrinth seal is formed between the furnace opening cover 32 and the rotation shaft 41 with the concavities and convexities and the convexities and concavities. Since the rotor 61 located at the lower side is covered with the upper side stator 62, even this construction can allow the upper clearance opening 63 communicating with a side of the reaction chamber to be located at a side of the rotation shaft rather that an opposite side of the rotation shaft, thereby being able to allow the clearance opening diameter R to be small. In the case of FIG. 3 where there is sufficient space in the radial direction, since the number of concavities and convexities can be increased, the sealing function can be further enhanced compared to the case of FIG. 1 where space is tight in the axial direction. In addition, the rotor 61 constructs the first convex portion and the stator 62 constructs the second convex portion.

Moreover, the present invention is particularly advantageous in the case that the present invention is applied to the vertical CVD apparatus in which flowing a gas from a side of a rotation center would influence a reaction. However, the present invention is applicable to a vertical type diffusion apparatus in which flowing a gas from a side of a rotation center would have little influence on a reaction.

According to the present invention, since an opening of the sealing portion clearance communicating with a side of the reaction chamber is located at a side of the rotation shaft rather than an opposite side of the rotation shaft and an opening diameter of the clearance with the rotation shaft as center is small, the opening area is smaller compared to a sealing portion which has a large opening diameter, thereby being able to effectively prevent a reaction gas inside of the reaction chamber from flowing into a rotation mechanism without injecting a gas from a clearance of the sealing portion. As a result, a malfunction in a rotation mechanism resulted from a reaction gas can be resolved.

The above-mentioned prevention of a reaction gas flowing into a rotation mechanism is also effective in a CVD apparatus in which a sealing portion is located at a side of a gas supply opening rather than a gas exhaust opening or the sealing portion is located at an upstream side of a reaction gas rather than the substrate to be processed.

What is claimed is:

1. A substrate processing apparatus for processing a substrate to be processed while rotating said substrate by a rotation shaft of a rotation mechanism during introducing a reaction gas into a reaction chamber as well as exhausting the reaction gas, the apparatus comprising:
a sealing portion for preventing a reaction gas from flowing into said rotation mechanism from said reaction chamber via a clearance which is formed, with said rotation shaft as center, between said rotation shaft and a non-rotational portion, which said rotation shaft penetrates, of said reaction chamber,
wherein an opening of said clearance communicating with a side of said reaction chamber is arranged at a side of said rotation shaft rather than an opposite side of said rotation shaft remote from said rotation shaft.

2. A substrate processing apparatus according to claim 1, wherein said reaction chamber is provided with a gas supply opening at one side of said reaction chamber and with a gas exhaust opening at the other side of said reaction chamber, and
wherein said sealing portion is arranged at a side of said gas supply opening rather than said gas exhaust opening.

3. A substrate processing apparatus according to claim 1, wherein said sealing portion is arranged at an upstream side of said reaction gas rather than said substrate to be processed.

4. A substrate processing apparatus according to claim 1, wherein said sealing portion is kept at a temperature of 150° C. or more.

5. A substrate processing apparatus according to claim 1, wherein said sealing portion is formed in such a way that a first convex portion extending from said rotation shaft and a second convex portion extending from said non-rotational portion are engaged with each other via a clearance.

6. A substrate processing apparatus for processing a substrate to be processed while rotating said substrate by a rotation shaft of a rotation mechanism during introducing a reaction gas into a reaction chamber as well as exhausting the reaction gas, the apparatus comprising:
a rotation shaft and a non-rotational portion, which said rotation shaft penetrates, of said reaction chamber; and
a sealing portion having a first convex portion extending from said rotation shaft and a second convex portion extending from said non-rotational portion, that is formed in such a way that said first and second convex portions are engaged with each other via a clearance,
wherein said second convex portion is located at a side of said substrate rather than said first convex portion.

7. A method for manufacturing a semiconductor device that processes a substrate to be processed while rotating said substrate by a rotation shaft of a rotation mechanism during introducing a reaction gas into a reaction chamber as well as exhausting the reaction gas, the method comprising:
forming a thin film on said substrate to be processed, by using a substrate processing apparatus which comprising:
a sealing portion for preventing a reaction gas from flowing into said rotation mechanism from said reaction chamber via a clearance which is formed, with said rotation shaft as center, between said rotation shaft and a non-rotational portion, which said rotation shaft penetrates, of said reaction chamber,
wherein an opening of said clearance communicating with a side of said reaction chamber is arranged at a side of said rotation shaft rather than an opposite side of said rotation shaft remote from said rotation shaft.

8. A method for manufacturing a semiconductor device according to claim 7, wherein said sealing portion is arranged at an upstream side of said reaction gas rather than said substrate to be processed.

9. A method for manufacturing a semiconductor device according to claim 7, wherein said sealing portion is formed in such a way that a first convex portion extending from said rotation shaft and a second convex portion extending from said non-rotational portion are engaged with each other via a clearance.
